(19) United States
(12) Patent Application Publication
(10) Pub. No.: US 2022/0379341 A1
(43) Pub. Date: Dec. 1, 2022

(54) METHOD AND APPARATUS FOR DEPOSITING ORGANIC LAYERS

(71) Applicant: AIXTRON SE, Herzogenrath (DE)

(72) Inventors: Hermann Albert GIESE, Roetgen (DE); Alexander GEORGI, Aachen (DE); Jan Raphael BINDEL, Ainring (DE); Dinesh Kanna SUBRAMANIAM, Aachen (DE); Tobias SCHÄFER, Aachen (DE); Dietmar KEIPER, Aachen (DE); Olaf Martin WURZINGER, Übach-Palenberg (DE)

(21) Appl. No.: 17/773,344

(22) PCT Filed: Oct. 28, 2020
(86) PCT No.: PCT/EP2020/080278

§ 371 Date: Apr. 29, 2022

(30) Foreign Application Priority Data
Oct. 29, 2019 (DE) 10 2019 129 176.3

(51) Int. Cl. B05D 1/00; B05C 19/04

(52) U.S. Cl. CPC B05D 1/60; B05C 19/04

(57) ABSTRACT

An apparatus for depositing organic layers on a substrate includes a gas-mixing device with one or more inlets, each for supplying a gas flow consisting of previously vaporized organic molecules that are conveyed by a carrier gas and have a molar mass greater than 300 g/mol or 400 g/mol, gas diversion elements which homogeneously mix the organic molecules in the carrier gas, and an outlet from which a homogeneous gas mixture discharges. The apparatus also comprises a conveying pipe which is connected to the outlet, and a gas inlet element that has a gas distribution volume, into which the conveying pipe leads and which has a gas outlet face that has gas outlet openings and faces a substrate holder for receiving the substrate. Furthermore, layers are deposited on the substrate using such an apparatus. The lateral homogeneity of the deposited layers is improved by one of several techniques.

The invention relates to a method for depositing layers onto a substrate, in which a gas flow consisting of previously evaporated organic molecules conveyed by a carrier gas and having a molar mass greater than 300 g/mol or 400 g/mol are supplied in one or several inlets of a gas mixing device, the molecules of the one or several gas flows are homogeneously mixed in the carrier gas through multiple diversion by means of gas diversion elements, the mixture generated in this way is guided as a gas flow from an outlet of the gas mixing device into a conveying pipe, conveyed through the conveying pipe into a gas distribution volume of a gas inlet element, discharged through gas outlet openings of the gas distribution volume in the direction toward a susceptor, and the molecules are deposited as an organic layer onto a substrate received by the substrate holder.

The invention further relates to an apparatus for implementing the method with a gas mixing device, which has one or several inlets, each for supplying a gas flow consisting of previously evaporated organic molecules conveyed by a carrier gas and having a molar mass greater than 300 g/mol or 400 g/mol, gas diversion elements, which homogeneously mix the gas flows with each other through multiple diversion, and an outlet, from which a homogeneous gas mixture discharges, with a conveying pipe that is connected to the outlet, and with a gas inlet element, which has a gas distribution volume, into which the conveying pipe leads, and which has a gas outlet face that has gas outlet openings and faces a substrate holder for receiving the substrate.

### PRIOR ART

DE 102014106523 A1 shows an apparatus for depositing layers onto substrates, in which two different gases are mixed in a mixing device and transported through a conveying pipe to a gas inlet element in the form of a showerhead. Previously known from DE 102014109196 A1 is an apparatus for evaporating an aerosol, which together with a carrier gas is transported into a gas distribution volume of a showerhead.

WO 2012/175128 A1 describes an apparatus for generating a vapor, which is brought into a gas inlet element through a conveying pipe.

The large-area deposition of layers comprised in particular of organic material, in particular for OLED's, takes place with a gas inlet element in the form of a showerhead, which has a gas distribution volume that is supplied by a conveying pipe. A gas mixing system is used to mix a homogeneous mixture of a vapor of molecules having a molar mass greater than 300 g/mol or greater than 400 g/mol, in particular ALQ₃ molecules, into a carrier gas. A gas flow of this mixture is supplied to the conveying pipe. The gas flow discharging from the conveying pipe is distributed within the gas distribution volume and enters into the process chamber through gas outlet openings of a gas outlet plate. The gas outlet openings are faced by the substrate, onto which the layer is deposited. In prior art, total pressures of about 1 mbar are used within the gas distribution chamber or the conveying pipe or the process chamber.

In experiments to diminish the total pressure within the gas distribution chamber, lateral irregularities in layer growth or in layer composition were observed.

### SUMMARY OF THE INVENTION

The object of the invention is to indicate measures with which the total pressure within the process chamber and the gas distribution chamber can be reduced to under 1 mbar, without the observed lateral inhomogeneities in layer growth or layer composition arising.

The object is achieved by the invention indicated in the claims, wherein the subclaims are not just advantageous further developments of the invention indicated in the secondary claims, but are also independent solutions of the object.

The invention is based upon the knowledge that the lateral inhomogeneities can be traced back to a segregation of the mixture supplied to the conveying pipe. During passage through the conveying pipe, the concentration of vapor molecules in the area of the center increases. A concentration gradient of the large molecules forms from the center toward the edge. This concentration gradient is traced back to a diffusion directed transverse to the flow (cross diffusion), the cause of which lies in a temperature inhomogeneity in the cross sectional surface of the conveying pipe. The paraboloid flow forms within the conveying pipe, in particular in the area of the section of the conveying pipe that is connected to the gas mixing device. This takes place with local accelerations or delays of the gas. The concomitant local energy change in the gas flow takes place adiabatically, as a consequence of which the temperature decreases in areas in which the gas is accelerated. This is the case in particular in the center of the gas flow, so that a temperature gradient forms that drops from the edge of the conveying pipe to its center. The latter is responsible for a thermal diffusion (thermophoresis) of the large, organic molecules to the center. Another cause for the segregation toward the center can lie in the shear stress gradient of the flow, which decreases from the edge toward the middle of the conveying pipe.

Examinations, in particular model calculations, have shown that the observed segregation can be avoided if the flow rate does not exceed an upper value and/or a quotient of the diameter of the conveying pipe and the average speed of the flow therein lies above a lower limit. If possible, the Mach number of the average flow rate should be less than 0.1. In particular, the average flow rate should thus be less than 40 m/s, 30 m/s, 20 m/s or 10 m/s. The value of a function with the arguments gas flow through the conveying pipe, pressure in the conveying pipe, temperature of the conveying pipe and diameter of the conveying pipe should lie below a limit that depends on a maximum permissible inhomogeneity of the deposited layer. For example, the maximum inhomogeneity of the layer (also the quotient of the maximum deviation from an average value and the average value of the layer thickness) should be no greater than 0.5 percent or no greater than 1 percent. Proposed in particular to achieve this are means with which the pressure within the conveying pipe is increased, for example to pressures within a range of 0.5 mbar or 1 mbar. The pressure barrier used to achieve this is preferably arranged at the end of the conveying pipe, and is located in particular within the gas distribution volume. The pressure barrier can have a plate with gas passage openings formed into a ring, which envelops a volume into which the gas mixture transported through the conveying pipe is supplied. The gas mixture passes through the gas passage openings into the gas distribution chamber. The pressure barrier can have an annular body provided with gas passage openings, which envelops a volume sealed by a floor, wherein the floor preferably has no gas passage openings, and lies opposite the mouth of the conveying pipe. Due to the pressure barrier, the pressure in the gas distribution chamber can measure less than one half, one fourth or one eighth of the pressure in the conveying pipe, but preferably no less than 1/10 or 1/20 of the pressure in the conveying pipe, which can preferably be greater than 1 mbar or 0.5 mbar. However, in order to adjust the flow rate or the aforementioned quotient, it is also possible to lay out the diameter of the conveying pipe accordingly. Diffusion influencing means can further be provided, which reduce, inhibit, or prevent the diffusion of large molecules directed transverse to the flow. The diffusion influencing means can be physical barriers, which divide the flow through the conveying pipe into several parallel partial flows, for example coaxial flows. The diffusion influencing means can be nested tubes, and/or extend over the entire length of the conveying pipe. The gas mixing device has at least one inlet, into which a mixture of an organic vapor in a carrier gas is supplied. The gas mixing device has a plurality of gas diversion elements, which repeatedly divert the gas flow, so that as perfect a mixture as possible forms at the outlet of the gas mixing device. In particular, it is provided that the gas mixing device has two or more inlets, through which mixtures of organic molecules that differ from each other are supplied. The differing organic molecules can be brought into vapor form by evaporating a solid or a liquid. To this end, a respective aerosol generator is preferably used, which generates an aerosol that is transported to an evaporator with a carrier gas supplied to the aerosol generator with a supply line, where the aerosol particles come into contact with heat transfer surfaces and evaporate. The differing vapors are mixed in the gas mixing device.

Examinations, in particular model calculations, have yielded the following correlation for ALQ₃ between inhomogeneity and average speed in the conveying pipe:

$$a * {( \frac{δ g}{{g}_{m}} )}^{0 , 636} > {v}_{m}$$

a=49.62 for ALQ₃
gₘ: Average value for layer thickness
δ_{g}: Maximum deviation of layer thickness from the average value
vₘ: Average value for the speed of the gas flow in the conveying pipe.

The following functional correlation arises for the average value for the speed of the gas flow in the conveying pipe:

$${v}_{m} = \frac{Q \cdot {P}_{0} \cdot T}{C \cdot P \cdot {T}_{0} \cdot {d}^{2}}$$

Q: Gas flow through the conveying pipe (sccm under standard pressure P₀ and at standard temperature T₀)
T: Temperature of the gas in the conveying pipe
P: Pressure of the gas in the conveying pipe
d: Diameter of the conveying pipe
C=1.5·10⁷·π

This yields the following inequality:

$$a * {( \frac{δ g}{{g}_{m}} )}^{0 , 636} > \frac{Q \cdot {P}_{0} \cdot T}{C \cdot P \cdot {T}_{0} \cdot {d}^{2}}$$

### BRIEF DESCRIPTION OF THE DRAWINGS

The invention will be explained below based upon exemplary embodiments. Shown on:

FIG. 1 is a schematic illustration of an apparatus according to the invention in longitudinal section,

FIG. 2 is a cutout from FIG. 1 relating to a second exemplary embodiment,

FIG. 3 is a cutout from FIG. 1 relating to a third exemplary embodiment,

FIG. 4 schematically is the parabolic speed profile in the conveying pipe 9,

FIG. 5 schematically is the temperature distribution within the conveying pipe 9,

FIG. 6 is the influence of the pressure P3 within the conveying pipe 9 on the irregularity of the deposited layer,

FIG. 7 is the influence of the average flow rate within the conveying pipe 9 on the temperature gradient (FIG. 5) in the conveying pipe 9,

FIG. 8 is the influence of the temperature gradient in the conveying pipe 9 on the irregularity of the deposited layer,

FIG. 9 is the influence of the average speed of the gas flow within the conveying pipe 9 on the irregularity of the deposited layer, and

FIG. 10 is the influence of the quotient Q/P (mass flow/pressure) within the conveying pipe 9 on the irregularity of the deposited layer.

### DESCRIPTION OF THE EMBODIMENTS

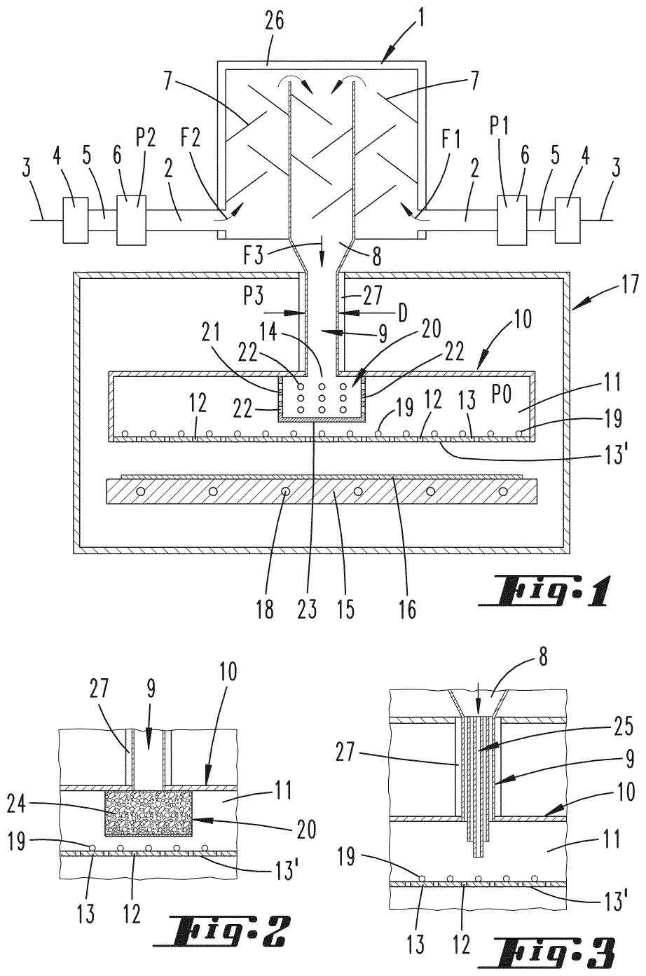

FIG. 1 schematically shows an apparatus according to the invention. The apparatus according to the invention can have at least one source of an organic vapor. This source has an aerosol generator 4, with which aerosol particles are generated from a solid or a liquid. The molecules of the aerosol particles have a molar mass of more than 300 g/mol or more than 400 g/mol. Preferably involved is aluminum-tris (8-hydroxychinolin), C₂₇H₁₈AlN₃O₃, with a molar mass of 459.43 g/mol. In the exemplary embodiment, several sources of differing organic molecules are provided. A carrier gas supply pipe 3 is provided, with which a carrier gas is supplied to the aerosol generator 4. The aerosol particles are transported by a heated aerosol pipe 5 to an evaporator 6, where an evaporation of the aerosol particles takes place at a pressure P1 or P2. The vapor generated in this way is supplied to an inlet 2 of a gas mixing device 1 through a heated pipe.

The gas mixing device 1 has a mixing chamber, which is kept by a heating device 26 at a temperature lying above the condensation temperature of the organic molecules. An at least once-diverted path extends within the mixing chamber, and carries the flow of mixture inhomogeneously supplied to the inlets 2, 2′. The flow of this mixture is repeatedly diverted by means of gas diversion elements 7, and diverted in such a way as to achieve as homogeneous a distribution of organic molecules as possible in the carrier gas in the area of the outlet 8.

As shown schematically on FIG. 1, the cross section of the path through which the mixture moves through the gas mixing device 1 diminishes in the area of the outlet 8, so that an increase in the speed of the gas flow takes place.

The outlet 8 of the gas mixing device 1 empties into a conveying pipe 9, which can be designed as a tube with a circular cross section. The conveying pipe 9 can have a cross sectional surface of 10-20 cm². The conveying pipe 9 is heated by a heating device 27 to a temperature, which can be the same temperature to which the gas mixing device 1 is also heated. However, the two temperatures can also differ from each other. Within the conveying pipe 9, the gas mixture has a pressure P3. In the exemplary embodiment, the conveying pipe 9 is located in the same housing 17 in which a gas inlet element 10 is also located.

The conveying pipe 9 empties into a gas distribution volume 11 of the gas inlet element 10. To this end, the gas inlet element 10 has a gas inlet opening 14, through which the gas mixture transported through the conveying pipe 9 can enter into the gas distribution volume 11. A floor of the gas distribution volume 11 forms a gas outlet plate 13 with a gas outlet face 13′. Gas outlet openings 12 are located in the gas outlet plate 13. The gas outlet openings 12 are evenly distributed across the gas outlet face 13′. The gas outlet openings 12 are directed toward a substrate 16, which is carried by a substrate holder 15 that is cooled by means of a coolant flowing through the coolant channels 18, such that the organic molecules can condense on the substrate 16. A heating device 19 is provided, with which in particular the gas outlet plate 13 or the walls of the gas inlet element 10 are heated to a temperature lying above the condensation temperature of the organic molecules.

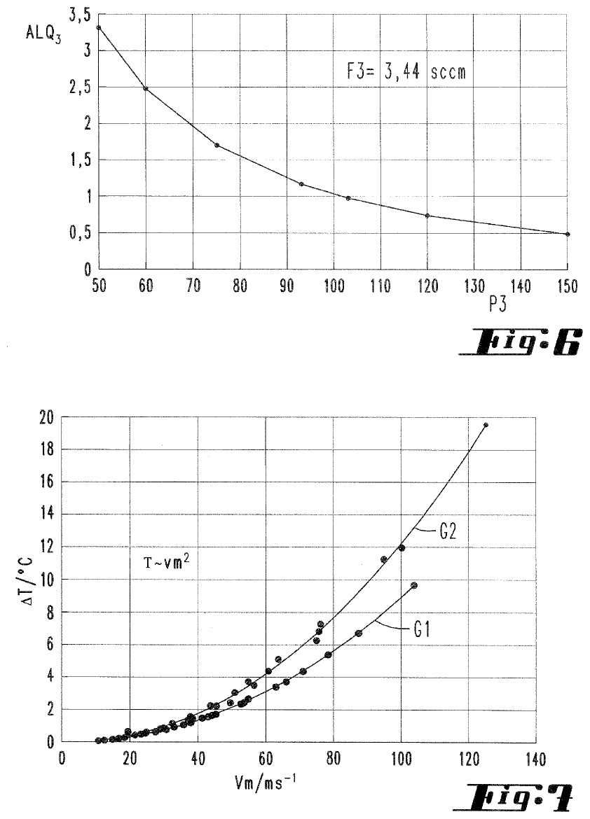

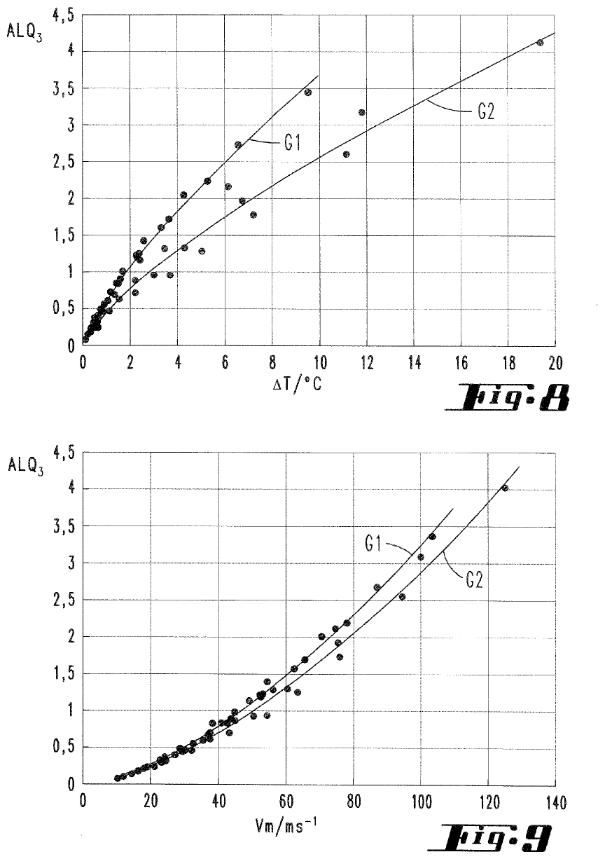

FIG. 4 shows a speed profile for the flow within the conveying pipe 9. The speed profile has a parabolic shape. The flow rate v is maximal in the center of the conveying pipe 9, and zero at the edge. During the formation of this flow in the area of the outlet 8 of the gas mixing device 1, volume elements of the gas mixture are accelerated or delayed. Given a correspondingly low total pressure or large flow rates, the concomitant adiabatic change in energy within the volume elements can lead to a temperature change, and in particular to a temperature drop in the center of the gas flow through the conveying pipe 9. This results in the temperature profile schematically shown on FIG. 5. Due to the larger cross sectional surfaces of the organic molecules in relation to the carrier gas, which can be nitrogen or hydrogen, a cross diffusion relative to the direction of flow takes place. The direction of diffusion is the radial direction, so that a segregation from the edge to the center forms. In the area of the gas inlet opening 14, the gas flow has a higher concentration of organic molecules in the center than at the edge. Given an apparatus according to prior art or when processing according to the process parameters used in prior art, this inhomogeneity is reflected in the distribution of the gas mixture in the gas distribution volume 11, so that gases with a differing concentration of organic molecules exit through different gas outlet openings at varying locations, which is manifested as an irregularity in the layer growth. FIGS. 6 to 10 show the influences of pressure and average speed on the irregularity of the layer growth.

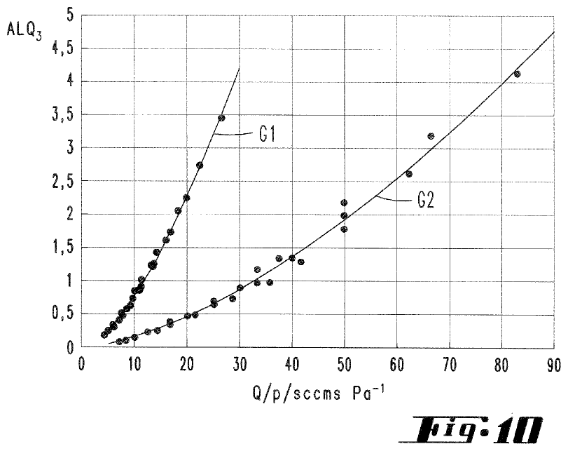

In order to avoid this irregularity, one aspect of the invention provides that the flow rate within the conveying pipe 9 be less than 40 m/s, less than 30 m/s, less than 20 m/s or less than 10 m/s. FIG. 9 shows the dependence of the irregularity of the layer, meaning the quotient between the largest distance of the layer thickness from the average value and the average value for the layer thickness as a function of the average flow rate through the conveying pipe 9. The conducted examinations show a nonlinear behavior. The irregularity rises with the exponents 1.572. The inverse function yields a critical average flow rate, which with an exponent of 0.636 depends on the desired degree of irregularity (in percent).

vₘ=0,00261×v^{1.572}ₑₘ

The nonuniformity of the layer thickness (δg/gₘ) can be kept in a permissible range through a selection of process parameters if the process parameters Q: gas flow through the conveying pipe (sccm under standard pressure P₀ and at standard temperature T₀), T: temperature of the gas in the conveying pipe, P: pressure of the gas in the conveying pipe and d: diameter of the conveying pipe are selected in such a way that the following inequality applies:

$$a * {( \frac{δ g}{{g}_{m}} )}^{0 , 636} > \frac{Q \cdot {P}_{0} \cdot T}{C \cdot P \cdot {T}_{0} \cdot {d}^{2}}$$

wherein a measures 49.62 for ALQ₃, but can be larger or smaller for other molecules, and wherein c measures 1.5·10⁷·π.

The invention further provides that the reduction in flow rate be achieved by a pressure barrier 20. The pressure barrier 20 shown on FIG. 1 is an annular body 21, which has a plurality of gas passage openings 22. The floor 23 seals the volume within the annular body 21. The floor 23 is spaced apart from the gas outlet plate 13, and can have no gas passage openings. The pressure barrier 20 makes it possible for the pressure P3 within the conveying pipe 9 to become no less than 1 mbar or no less than 0.6 mbar, 0.5 mbar or no less than 0.3 mbar. However, the pressure PO within the gas distribution volume 11 can be distinctly lower. It can be less than 1 mbar, less than 0.6 mbar or less than 0.3 mbar. The gas passage openings 22 can be located in a thin-walled plate formed into a ring, which envelops a volume that is sealed by a floor plate 23 to the first end face, and open to a second end face toward the conveying pipe 9.

The exemplary embodiment depicted on FIG. 2 shows a pressure barrier 20, which is comprised of an open-pored foam. In the exemplary embodiment shown on FIG. 1, the gas passage openings 22 act as a pressure barrier. In the exemplary embodiment shown on FIG. 2, these are the channels in the solid foam formed by the pores.

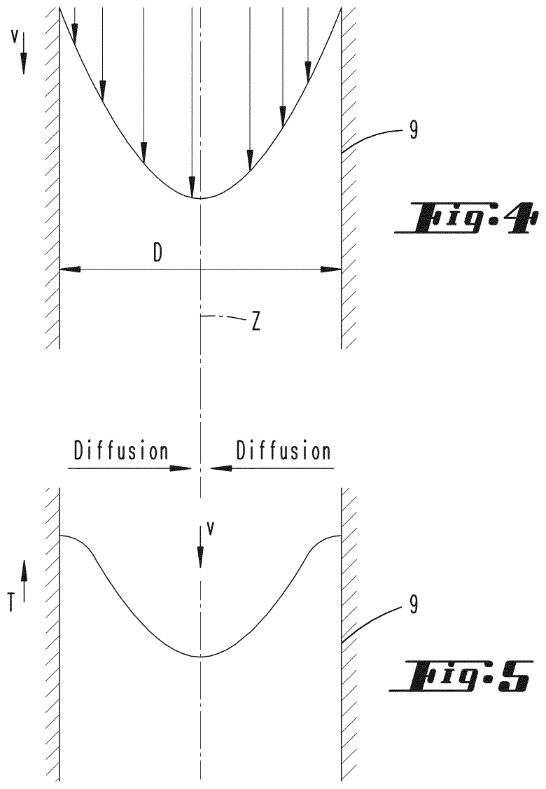

FIG. 3 shows an alternative concept for achieving the object. Diffusion barriers 25 are provided, with which the cross diffusion described above is avoided. These can be concentric tubes, which divide the conveying pipe 9 into flow channels that are separated from each other.

The diffusion influencing means 25 can extend over the entire length of the conveying pipe 9, the diameter of which in particular is less than an average diameter of a flow path within the gas mixing device 1 and/or is less than a cross sectional surface of the gas distribution volume 11.

In particular, it is provided and/or tolerable that the gas flow being discharged from the gas mixing device 1 be accelerated while entering into the conveying pipe 9 in such a way that the gas temperature in the center of the gas flow decreases. According to the invention, however, the temperature difference of the gas flow at the edge of the conveying pipe 9 is so low that inhomogeneous layer growth is avoided, or confined to a tolerable minimum.

While the measures described above do not enable a 100% reduction in the temperature gradient or a gradient of shear forces in the flow, the gradient can be limited to a magnitude at which its technological relevance is eliminated, i.e., layers are deposited whose irregularity lies below a predefined limit, so that the result is technologically acceptable.

The above statements serve to explain the inventions covered by the application as a whole, which each also independently advance the prior art at least by the following feature combinations, wherein two, several or all of these feature combinations can also be combined, specifically:

A method, characterized in that the average flow rate vₘ in the conveying pipe 9 is selected in such a way, the conveying pipe 9 has diffusion influencing means 25 that are designed in such a way, or a pressure barrier 20 at the end of the conveying pipe 9 facing the gas inlet element 10 is provided in such a way as to at least inhibit, preferably prevent, a segregating diffusion of organic molecules, which is directed in the center of the cross section of the conveying pipe 9 and causes a lateral, inhomogeneous layer growth.

An apparatus, characterized in that the conveying pipe 9 has a cross sectional surface, diffusion influencing means 25, or that a pressure barrier 20 is provided at its end facing the gas inlet element 1, so as to at least inhibit, preferably prevent, a segregating diffusion of the organic molecules, which is directed toward the center of the cross section of the conveying pipe 9 and causes a lateral, inhomogeneous layer growth.

A method or an apparatus, characterized in that the pressure barrier 20 is an in particular annular throttle within the gas distribution volume 11 and/or is a plate provided with gas passage openings 22 and extending in particular on a cylindrical shell surface and/or has an open-pored foam body 24.

A method or an apparatus, characterized in that the diffusion influencing means 25 have a barrier that acts at least in the radial direction, and extends in the axial direction of the conveying pipe 9.

A method or an apparatus, characterized in that the total pressure P3 in the conveying pipe 9, the mass flow of the mixture through the conveying pipe 9 and the diameter D of the conveying pipe 9 are selected in such a way that the average flow rate vₘ is less than 40 m/s, 30 m/s, 20 m/s or preferably less than 10 m/s and/or that the total pressure

P0 in the gas distribution volume 11 is preferably less than 0.9 mbar, 0.6 mbar, 0.3 mbar or 0.1 mbar.

A method or an apparatus, characterized by the following parameters:
Q: Gas flow through the conveying pipe 9 (sccm under standard pressure P₀ and at standard temperature T₀)
T: Temperature of the gas in the conveying pipe 9
P: Pressure of the gas in the conveying pipe 9, and
d: Diameter of a circle equivalent cross sectional surface of the conveying pipe 9
   satisfying the following inequality

$$a * {( \frac{δ g}{{g}_{m}} )}^{0 , 636} > \frac{Q \cdot {P}_{0} \cdot T}{C \cdot P \cdot {T}_{0} \cdot {d}^{2}}$$

wherein a is a molecule-dependent value that measures 49.62 M/s for ALQ₃,
C=1.5·10⁷π and the quotient δg/gₘ is the maximum permissible inhomogeneity, in particular deviation of the layer thickness at any point of the layer from the average layer thickness, wherein δg/gₘ is preferably 0.5 percent or 1 percent.

A method or an apparatus, characterized by at least two evaporation apparatuses 6 for respectively evaporating aerosol particles that consist of the organic molecules and were brought into the carrier gas flow, wherein it is provided in particular that the aerosol particles of the organic molecules differing from each other are evaporated at differing temperatures and/or at differing total pressures and/or are supplied to the gas mixing device in inlets 2, 2′ differing from each other.

A method or an apparatus, characterized by a first temperature control unit 26, with which the gas mixing device is heated to a first temperature, and by a second temperature control unit 27, with which the conveying pipe is heated to a second temperature.

All disclosed features (whether taken separately or in combination with each other) are essential to the invention. The disclosure of the application hereby also incorporates the disclosure content of the accompanying/attached priority documents (copy of the prior application) in its entirety, also for the purpose of including features of these documents in claims of the present application. Even without the features of a referenced claim, the subclaims characterize standalone inventive further developments of prior art with their features, in particular so as to submit partial applications based upon these claims. The invention indicated in each claim can additionally have one or several of the features indicated in the above description, in particular those provided with reference numbers and/or indicated on the reference list. The invention also relates to design forms in which individual features specified in the above description are not realized, in particular if they are recognizably superfluous with regard to the respective intended use, or can be replaced by other technically equivalent means.

Reference List

| | | | |
|---|---|---|---|
| 1 | Gas mixing device | 25 | Diffusion barrier |
| 2 | Inlet | 26 | Heating device |
| 2′ | Inlet | 27 | Heating device |
| 3 | Carrier gas supply pipe | | |
| 4 | Aerosol generator | | |
| 5 | Aerosol pipe | | |
| 6 | Evaporator | | |
| 7 | Gas diversion element | | |
| 8 | Outlet | | |
| 9 | Conveying pipe | | |
| 10 | Gas inlet element | D | Diameter |
| 11 | Gas distribution volume | F1 | Gas flow |
| 12 | Gas outlet opening | F2 | Gas flow |
| 13 | Gas outlet plate | P0 | Pressure |
| 13' | Gas outlet surface | P1 | Pressure |
| 14 | Gas inlet opening | P2 | Pressure |
| 15 | Substrate holder | P3 | Pressure |
| 16 | Substrate | | |
| 17 | Housing | | |
| 18 | Coolant channel | | |
| 19 | Heating device | v | Flow rate |
| 20 | Pressure barrier | vₘ | Average flow rate |
| 21 | Annular body | | |
| 22 | Gas passage opening | | |
| 23 | Floor | | |
| 24 | Foam body | | |

1. A method for depositing an organic layer onto a substrate, the method comprising:
flowing a gas flow (F1, F2) comprising organic molecules conveyed by a carrier gas and having a molar mass greater than 300 g/mol into one or several inlets (2, 2′) of a gas mixing device (1);
mixing by gas diversion elements (7) the organic molecules in the carrier gas to form a homogeneous gas mixture;
flowing the homogeneous gas from an outlet (8) of the gas mixing device (1) into a conveying pipe (9);
flowing the homogeneous gas mixture from the conveying pipe (9) into a gas distribution volume (11) of a gas inlet element (1);
discharging the homogeneous gas mixture through gas outlet openings (12) of the gas distribution volume (11) toward a substrate holder (15); and
depositing the homogeneous gas mixture onto a substrate (16) supported on the substrate holder (15) so as to form the organic layer, wherein an average flow rate (vₘ) in the conveying pipe (9) is selected, the conveying pipe (9) has diffusion influencing means (25) that are designed, or a pressure barrier (20) at the an end of the conveying pipe (9) facing the gas inlet element (10) is provided to inhibit, a segregating diffusion of the organic molecules, which is directed in a center (Z) of a cross section of the conveying pipe (9) and causes a lateral, inhomogeneous layer growth of the organic layer.

2. An apparatus for implementing the method of claim 1, wherein the conveying pipe (9) has:
a cross sectional surface at which a flow rate of nitrogen or hydrogen in the carrier gas is less than 40 m/s so as to achieve a total pressure (P0) in the gas distribution volume (11) of less than 0.9 mbar,
diffusion influencing means (25) that divide a flow through the conveying pipe (9) into several parallel partial flows, or
a pressure barrier (20) disposed at an end of the conveying pipe (9) and facing the gas inlet element (1) with which the total pressure (P0) in the gas distribution volume (11) is reduced to less than half of a pressure in the conveying pipe (9),
wherein the cross sectional surface, the diffusion influencing means (25) and the pressure barrier (20) are configured to prevent the segregating diffusion of the organic molecules.

3. The apparatus of claim 2, wherein the pressure barrier (20) is an annular throttle disposed within the gas distribution volume (11).

4. The apparatus of claim 2, wherein the pressure barrier (20) is a plate provided with gas passage openings (22) and extending on a cylindrical shell surface.

5. The apparatus of claim 2, wherein the pressure barrier (20) has an open-pored foam body (24).

6. The apparatus of claim 2, wherein the diffusion influencing means (25) includes a barrier that acts at least in a radial direction of the conveying pipe (9), and extends in an axial direction of the conveying pipe (9).

7. The method of claim 1, wherein a total pressure (P3) in the conveying pipe (9), a mass flow of the homogenous gas mixture through the conveying pipe (9) and a diameter (D) of the conveying pipe (9) are selected so that the average flow rate (vₘ) is less than 40 m/s.

8. The method of claim 1, wherein a total pressure (P0) in the gas distribution volume (11) is less than 0.9 mbar.

9. The method of claim 1, wherein:
a mass flow, Q, of the homogeneous gas mixture through the conveying pipe (9) with units of standard cubic centimeter per minute (sccm) under standard pressure P₀ and at standard temperature T₀),
a temperature, T, of the homogeneous gas mixture in the conveying pipe (9),
a pressure, P, of the homogeneous gas mixture in the conveying pipe (9), and
d: a diameter, d, of a cross sectional surface of the conveying pipe (9) satisfy
$$a * {( \frac{δ g}{{g}_{m}} )}^{0 , 636} > \frac{Q \cdot {P}_{0} \cdot T}{C \cdot P \cdot {T}_{0} \cdot {d}^{2}}$$
wherein a is a molecule-dependent value,
wherein C=1.5·10⁷·π and
wherein δg/gₘ is a maximum permissible inhomogeneity, defined as a maximum deviation of a thickness at any point of the organic layer from an average thickness of the organic layer divided by the average thickness of the organic layer.

10. The apparatus of claim 2, further comprising a first evaporation apparatus (6) for evaporating a first type of aerosol particles, and a second evaporation apparatus (6) for evaporating a second type of aerosol particles.

11. The apparatus of claim 10, wherein the first and second types of aerosol particles are evaporated at differing temperatures or at differing total pressures.

12. (canceled)

13. The apparatus of claim 10, wherein the first type of aerosol particles are supplied to the gas mixing device (1) via a first inlet (2) and the second type of aerosol particles are supplied to the gas mixing device (1) via a second inlet (2) differing from the first inlet (2).

14. The apparatus of claim 2, further comprising a first temperature control unit (26) configured to heat, the gas mixing device (1) to a first temperature, and a second temperature control unit (27) configured to heat the conveying pipe (9) to a second temperature.

15. (canceled)

16. The method of claim 9, wherein a equals 49.62 M/s when the gas flow includes ALQ₃.
